(19) United States
(12) Patent Application Publication
(10) Pub. No.: US 2019/0357360 A1
(43) Pub. Date: Nov. 21, 2019

(54) Methods for Preparing Electrically Conductive Patterns and Articles Containing Electrically Conductive Patterns

(71) Applicant: 3M INNOVATIVE PROPERTIES COMPANY, St Paul, MN (US)

(72) Inventors: Meredith M. Doyle, St. Paul, MN (US); Matthew H. Frey, Cottage Grove, MN (US)

(21) Appl. No.: 16/473,936

(22) PCT Filed: Dec. 27, 2017
(86) PCT No.: PCT/IB2017/058436

§ 371 Date: Jun. 26, 2019

Related U.S. Application Data
(60) Provisional application No. 62/439,965, filed on Dec. 29, 2016.

(51) Int. Cl. H05K 3/24; H05K 3/00; H05K 3/12; H05K 1/09; H05K 1/03

(52) U.S. Cl. CPC H05K 3/247; H05K 3/0017; H05K 2201/026; H05K 1/097; H05K 1/036; H05K 3/1258

(57) ABSTRACT

Conductive articles include an electrically insulating substrate with conductive regions on the substrate, the conductive regions are conductive patterns of a transparent conductor and a resist matrix. The substrate also has non-conductive regions, and exposed conductive contacts, where the conductive contacts are in electrical contact with the conductive regions. The non-conductive regions are formed by selective chemical etching of the transparent conductor coating, where the selective etching does not remove the conductive patterns or conductive contact.

### FIELD OF THE DISCLOSURE

This disclosure relates to methods for preparing patterned, electrically conductive articles and the patterned, electrically conductive articles prepared with these methods.

### BACKGROUND

There is an ever increasing need to develop and produce electronic devices with new characteristics. Among the important characteristics are electrically conductive patterns. A wide array of techniques have been used to form electrically conductive patterns, but with the need for the electrically conductive patterns to be smaller and smaller, it has become increasingly difficult to produce these electrically conductive patterns in a manner that is both reliable and cost-effective.

Additionally, many devices and articles that utilize electrically conductive patterns additionally require that the electrically conductive patterns be transparent, that it is to say that the electrically conductive patterns transmit visible light, and preferably are not visible to the human eye. These electrically conductive patterns may comprise transparent conductors. Transparent conductors are utilized on a wide range of articles such as touch screens to enable human touch or gesture interactions with computers, smart phones, and other graphics based screen interfaces.

Among the methods for preparing electrically conductive patterns are printing techniques using conductive inks such as silver inks. However there are limitations on the size of patterns that can be printed, and often the printed patterns are not transparent.

Recently transparent conductors have been prepared through the use of nanowires. For example, PCT publication WO 2007/022226 entitled “Nanowires-Based Transparent Conductors” discloses a nanowire material sold by Cambrios Technologies Corporation that can be patterned into a suitable grid to enable the production of touch screens for use with computers.

Methods for patterning the nanowires into conductive and non-conductive regions (e.g., regions that comprise interconnected nanowires and regions that do not comprise interconnected nanowires, respectively) have also been reported. Some of those methods are based on wet chemical etching of the nanowires. For example, U.S. Pat. No. 8,018,568 entitled “Nanowire-based Transparent Conductors and Applications Thereof” describes chemical etching silver nanowire transparent conductor patterns with an aqueous solution comprising nitric acid, sodium nitrate, and potassium permanganate. U. S. Patent Application No. US20010253668 entitled “Etch Patterning of Nanostructure Transparent Conductors” describes chemical etching of silver nanowire transparent conductor patterns with aqueous solutions comprising acids and metal halides (e.g., iron chloride, copper chloride). U.S. Pat. No. 8,225,238 entitled “Systems, Devices, and Methods for Controlling Electrical and Optical Properties of Transparent Conductors” discusses strategies for formulating an aqueous etchant for silver nanowires, based on combination of an oxidizing agent (e.g., permanganate, hydrogen peroxide, oxygen) with a compatible counter-ion for the silver ion (e.g., nitrate, cyanide).

### SUMMARY

Disclosed herein are conductive articles and methods of preparing conductive articles. In some embodiments, the conductive article comprises an electrically insulating substrate with a conductive region on the substrate, the conductive region comprising a conductive pattern comprising a transparent conductor and a resist matrix, a non-conductive region on the substrate, and an exposed conductive contact comprising a first major surface and a second major surface. A portion of the first major surface of the conductive contact is in contact with the transparent conductor, and a portion of the first major surface of the conductive contact is in contact with a portion of the resist matrix, and wherein the second major surface of the conductive contact is exposed.

Also disclosed are methods of preparing conductive articles. In some embodiments, the method of preparing a conductive article comprises preparing a precursor article, and chemically etching the precursor article. Preparing the precursor article comprises providing an electrically insulating substrate comprising an substantially continuous transparent conductor coating over at least a portion of the substrate surface, selectively applying a resist matrix material to portions of the substantially continuous transparent conductor coating to yield a pattern of resist matrix material with an exposed surface, and selectively applying a conductive contact composition in a pattern to portions of the transparent conductor coating surface, and to at least portions of the exposed surface of the resist matrix material. The conductive coating surface is thus divided into subregions, the subregions comprising first subregions comprising the transparent conductor coating exposed, second subregions comprising the transparent conductor coating and the pattern of resist matrix material, and third subregions comprising the transparent conductive coating in contact with the conductive contact composition pattern, where the conductive contact composition pattern is also in contact with a portion of the formerly exposed surface of the resist matrix material. The resist matrix material can be optionally cured or dried if appropriate and the conductive contact material likewise can be optionally cured or dried if appropriate. The chemical etching of the precursor article is carried out such that the transparent conductor coating in the first subregions comprising the exposed transparent conductor coating is selectively removed, but the transparent conductor coating in the second subregions comprising the transparent conductive coating and the resist matrix and the transparent conductor coating in the third subregions comprising the transparent conductive coating in contact with the conductive contact are not removed or are not completely removed.

In other embodiments of conductive articles, the conductive article comprises an electrically insulating substrate, a conductive region on the substrate, the conductive region comprising a conductive pattern comprising a transparent conductor and a resist matrix, a non-conductive region on the substrate, and an exposed conductive contact comprising a first major surface and a second major surface, where the entire first major surface of the conductive contact is in contact with the transparent conductor, wherein at least a portion of the second major surface of the conductive contact is exposed and optionally wherein at least a portion of the second major surface of the conductive contact is in contact with the resist matrix.

In other embodiments of methods, the method of preparing a conductive article comprises preparing a precursor article, and chemically etching the precursor article. Preparing the precursor article comprises providing an electrically insulating substrate comprising an substantially continuous transparent conductor coating over at least a portion of the substrate surface, selectively applying a conductive contact composition in a pattern to portions of the transparent conductor coating to form a conductive contact with an exposed surface, and selectively applying a resist matrix material to portions of the substantially continuous transparent conductor coating in a pattern, and optionally to a portion of the exposed surface of the conductive contact composition. The conductive coating surface is thus divided into subregions, the subregions comprising first subregions comprising the transparent conductor coating exposed, second subregions comprising the transparent conductor coating and the pattern of resist matrix material, and third subregions comprising the transparent conductive coating in contact with the conductive contact composition pattern, where optionally a portion of the conductive contact composition pattern is in contact with the resist matrix material. The resist matrix material can be optionally cured or dried if appropriate and the conductive contact material likewise can be optionally cured or dried if appropriate. The chemical etching of the precursor article is carried out such that the transparent conductor coating in the first subregions comprising the exposed transparent conductor coating is selectively removed, but the transparent conductor coating in the second subregions comprising the transparent conductive coating and the resist matrix and the transparent conductor coating in the third subregions comprising the transparent conductive coating in contact with the conductive contact are not removed or are not completely removed.

### BRIEF DESCRIPTION OF THE DRAWINGS

The present application may be more completely understood in consideration of the following detailed description of various embodiments of the disclosure in connection with the accompanying drawings.

FIGS. 1A-1D show cross sectional views of the steps involved in the preparation of an article of this disclosure.

FIG. 1E shows a top view of the article of FIG. 1D.

FIGS. 2A-2D show cross sectional views of the steps involved in the preparation of another article of this disclosure.

FIG. 2E shows a top view of the article of FIG. 2D.

In the following description of the illustrated embodiments, reference is made to the accompanying drawings, in which is shown by way of illustration, various embodiments in which the disclosure may be practiced. It is to be understood that the embodiments may be utilized and structural changes may be made without departing from the scope of the present disclosure. The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

There is an ever increasing need to produce electrically conductive patterns on substrates. A wide array of techniques have been used to form such electrically conductive patterns. The techniques may be characterized as one of two process types, an additive process or a subtractive process. In an additive process, the pattern is formed by applying an electrically conductive material to a substrate directly in a pattern. Examples of such techniques include printing, where an electrically conductive ink is applied in a pattern. In subtractive processes, a substantially continuous conductive layer is applied to a substrate and portions of the substantially continuous conductive layer are then selectively removed to leave behind a pattern.

Both of these techniques have advantages and disadvantages. As mentioned above, printing becomes increasingly difficult as the size of the pattern becomes smaller and smaller and variations in the print thickness due to defects such as ribbing and pinholes may produce unacceptable variations in conductivity and visual appearance. The development of nanowire layers has made subtractive techniques attractive for preparing electrically conductive patterns that are transparent conductors, since the nanowire layers are generally transparent or produce low visibility conductive traces. One technique that has been developed for preparing transparent conductive patterns using subtractive techniques is described in PCT Publication No. WO 2014/088950 which describes such a process.

A particular challenge that arises in the use of patterned transparent conductors based on nanowires is simultaneously achieving electrical contact to a transparent conductive nanowire pattern element and protecting the nanowire pattern element from environmental factors that may degrade electrical properties (e.g., atmospheric corrosive species). These requirements may be met in part by introduction of additional materials: a transparent resist matrix that overlays and protects the nanowires in the region of the transparent conductive pattern element and an electrically conductive contact material in electrical contact with the transparent conductive pattern element. The practical implementation of these multiple materials necessarily includes their patterning in registration, such that the conductive contact and the resist matrix are each positioned in predetermined locations relative to the nanowire transparent conductor, which is itself patterned. The patterning of these multiple materials in registration may be achieved by various multi-step processes. Some processes may be preferred over other processes, for example on the basis of technical effect or on the basis of simplicity or cost. One criterion for process preference is the number of steps in the process, with more preferred processes having fewer process steps. Another criterion for process preference is the avoidance of particularly challenging steps. The present disclosure report multi-step processes for the patterning in registration of a transparent resist matrix, an electrically conductive contact material, and a nanowire transparent conductor, with the advantage of a small number of process steps and with the advantage of avoiding the need to remove some or all of a resist matrix.

An embodiment of the patterning process of PCT Publication No. WO 2014/088950 can be performed by the following sequence of steps: Coating a substrate with a conductive layer such as a nanowire layer. Optionally hardening or curing the nanowire layer. Applying a pattern on the nanowire layer with a resist matrix material to generate on the substrate one or more first regions of exposed nanowire layer and one or more second regions of the resist matrix material (typically a circuit pattern for a touch screen). Hardening or curing the resist matrix material. Over coating the pattern with a strippable polymer layer. Hardening or curing the strippable polymer layer. Peeling the strippable polymer layer from the substrate, removing the nanowire material in one or more first regions of the substrate and thereby forming a patterned nanowire layer. In another approach, the nanowire material can be replaced with a conductive polymer such as PEDOT and the same process used to pattern the conductive PEDOT layer.

The present disclosure is to a subtractive method of forming an electrically conductive pattern using a wet chemical etching process to remove transparent conductive material, instead of a strippable polymer layer as in PCT Publication No. WO 2014/088950. PCT Publication No. WO 2014/088950 specifically teaches that wet chemical etching and laser ablation techniques are less desirable since these techniques have undesirable process limitations.

However, the present disclosure includes techniques to overcome undesirable process limitations. In particular, the addition of an electrically conductive contact material (for example a conductive paste) can be done prior to the wet chemical etching process. Since the electrically conductive patterns generally contain discrete electrical traces that must be addressed individually with separate electrical signals, for example a series of parallel lines of conductive material, in order for the electrically conductive pattern to be useful, each of these discrete traces must be electrically connected to a separate conductive contact. Typically each conductive contact is a strip of metallic conductor to which a conductive trace connects. A conductive article may comprise a plurality of transparent conductive traces, each in electrical contact with a separate conductive contact in the form of a strip of metallic conductor (e.g., printed conductive paste, or patterned metal thin film). Other electrical contacts include contact pads. One difficulty with techniques that use subtractive processes to form an electrically conductive pattern where the conductive traces of the pattern are covered by an insulating resist matrix material, is that these insulated conductive traces must subsequently be joined to the conductive contact, and the resist matrix material interferes with the forming of these contacts.

Thus, the present disclosure includes methods which form articles that include not only electrically conductive patterns which are covered with a protective resist matrix material, but also include conductive contacts to give a completed conductive pathway. Prior to removal of the transparent conductive material from the substantially continuous transparent conductive layer by the wet chemical etching process, an electrical contact material (such as derived from a conductive paste) is applied which forms a conductive contact to what will become the electrically conductive pattern. In this way a conductive pathway including the electrically conductive pattern and the conductive contact is formed prior to the removal of at least a portion of the transparent conductive material.

One concern in using wet chemical etching techniques to remove the transparent conductive material to form the electrically conductive pattern while the conductive contact, which is an exposed metal or metal-containing layer, is also present, is that the conductive contact could also be etched away. However, the methods of the present disclosure have been designed to overcome this concern such that the wet chemical etching essentially completely removes the transparent conductive material in regions not protected by the resist matrix but does not completely remove the conductive contact.

Thus, disclosed herein are two methods of making conductive articles. The first method of preparing a conductive article comprises preparing a precursor article, where preparing the precursor article comprises providing an electrically insulating substrate comprising an substantially continuous transparent conductor coating over at least a portion of the substrate surface, selectively applying a protective resist matrix material to portions of the substantially continuous transparent conductor coating in a pattern, and then selectively applying a conductive contact composition in a pattern to portions of substantially continuous transparent conductor coating such that the conductive coating surface is divided into subregions. The subregions comprise first subregions comprising the transparent conductor coating exposed, second subregions comprising the transparent conductor coating and the protective resist matrix material, and third subregions comprising the conductive coating in contact with the conductive contact composition pattern. The precursor article is then chemically etched such that the conductive coating is selectively removed from the first subregions, and the conductive coating in the second subregions comprising the conductive coating and the protective resist matrix, and the conductive coating in the third subregions comprising the conductive coating in contact with a conductive paste pattern are not removed or are not completely removed.

The second method of preparing a conductive article comprises preparing a precursor article, where preparing the precursor article comprises providing an electrically insulating substrate with an substantially continuous transparent conductor coating over at least a portion of the substrate surface, selectively applying a conductive contact composition in a pattern to portions of substantially continuous transparent conductor coating, and then selectively applying a protective resist matrix material to portions of the substantially continuous transparent conductor coating in a pattern, and optionally on a portion of the conductive paste composition such that the conductive coating surface is divided into subregions. The subregions comprise first subregions comprising the transparent conductor coating exposed, second subregions comprising the transparent conductor coating and the protective resist matrix material, and third subregions comprising the conductive coating in contact with the conductive contact composition pattern. The precursor article is then wet chemically etched such that the conductive coating is selectively removed from first subregions, and the conductive coating in the second subregions comprising the conductive coating and the protective resist matrix, and the conductive coating in the third subregions comprising the conductive coating in contact with a conductive contact composition pattern are not removed or are not completely removed.

Also disclosed herein are the articles prepared by the methods described above.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. The recitation of numerical ranges by endpoints includes all numbers subsumed within that range (e.g. 1 to 5 includes 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise. For example, reference to “a layer” encompasses embodiments having one, two or more layers. As used in this specification and the appended claims, the term “or” is generally employed in its sense including “and/or” unless the content clearly dictates otherwise.

Unless otherwise indicated, “optically transparent” refers to an article or film that has a high light transmittance over at least a portion of the visible light spectrum (about 400 to about 700 nm). The term “transparent film” refers to a film having a thickness and when the film is disposed on a substrate, an image (disposed on or adjacent to the substrate) is visible through the thickness of the transparent film. In many embodiments, a transparent film allows the image to be seen through the thickness of the film without substantial loss of image clarity. In some embodiments, the transparent film has a matte or glossy finish.

Unless otherwise indicated, “resist matrix” and “resist matrix material” (used interchangeable with “protective resist matrix” and “protective resist matrix material”) refers to a matrix and the material from which the matrix is comprised, that is typically a transparent material and that when applied to a conductive coating can at least partially protect the conductive coating from removal by wet chemical etching. The material may be a curable or suspended material that upon curing or drying forms the resist matrix, or the material may be a 100% solids material that upon application forms the resist matrix.

Unless otherwise indicated, “conductive contact” refers to an electrically conductive material that is in electrical contact with a conductive coating, where the conductive contact is derived from a conductive contact composition. The terms “conductive contact material” and “conductive contact composition” are used interchangeably and refer to compositions that form conductive contacts, typically upon drying. Examples of conductive contact compositions include, for example, conductive pastes, inks, or thin films, configured in the form of contact pads or interconnect traces. Conductive contact compositions are applied to articles to form conductive contacts.

Disclosed herein are methods for preparing conductive articles useful in a wide range of electronic articles such as touch screens. These conductive articles typically have a plurality of conductive traces. Typically these conductive traces are transparent meaning that they the traces are generally not visible to the human eye. These conductive traces are sometimes referred to as comprising transparent conductors. There are many conductive materials that could be used as transparent conductors in, for example, a touch screen, ranging from metals (e.g., open mesh patterns) and metal oxides, such as indium tin oxide (ITO), conductive polymers, such as PEDOT, or metal nanowires, such as the material described in U.S. Pat. No. 8,049,333 (Alden et al.). These materials must meet a variety of desired specifications for conductivity and optical transparency. The process outlined in this document discloses a method for patterning such conductive materials to produce low-visibility conductive traces with conductive contacts, for use in a touch sensor.

This disclosure includes two closely related embodiments of methods for preparing conductive articles with a patterned transparent conductor, for example an article comprising a plurality of conductive traces with electrical contacts. These embodiments are explained in greater detail below with reference to the accompanying Figures.

In the first embodiment of the method of preparing a conductive articles, a precursor article is prepared. As used herein, the term precursor article refers to an article that can be etched to form the articles of this disclosure. Of course, as is well understood in the art, the articles of this disclosure could themselves be viewed as precursor articles since they are used in the assembly of electronic devices. For example, to prepare an electronic device, a conductive article of the present disclosure may be attached by adhesive lamination to another conductive article, a display, or a display cover glass. However, as used herein, precursor articles refer to those articles that can be wet chemically etched to prepare articles with a conductive pattern, for example conductive traces.

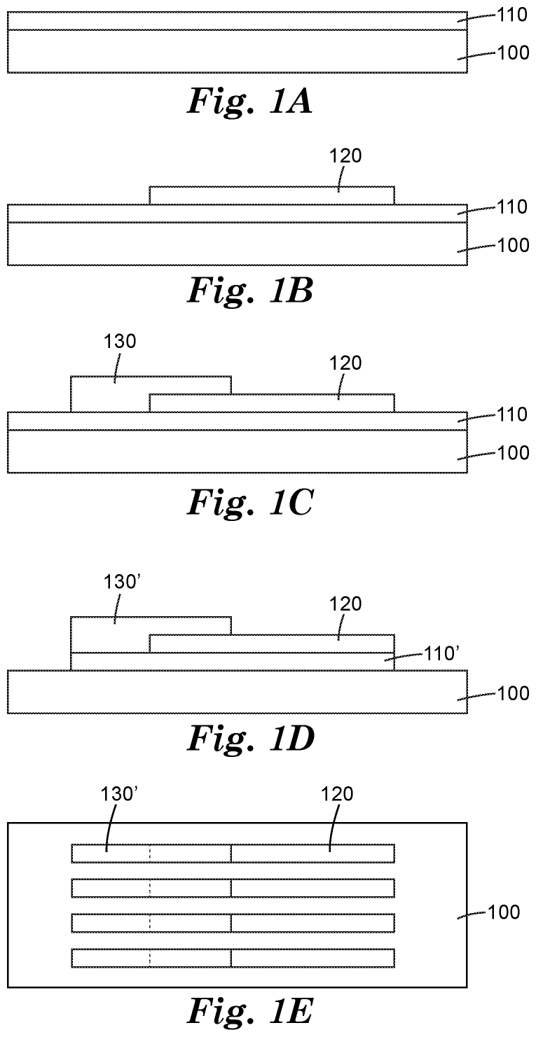

A first step in the preparation of the precursor article is providing an electrically insulating substrate with a substantially continuous transparent conductor coating over at least a portion of the substrate surface. This article is shown in FIG. 1A, which shows substrate 100 with transparent conductor coating 110.

A wide range of electrically insulating substrates are suitable for use in preparing the articles of this disclosure. As used herein, the term “substrate” refers to a material onto which the conductive layer or nanowire layer is coated or laminated. The substrate 100 can be rigid or flexible. The substrate can be clear or opaque. For the preparation if transparent conductive articles, optically transparent or optically clear substrates are particularly desirable. Suitable rigid substrates include, for example, glass, polycarbonates, acrylics, and the like. Suitable flexible substrates include, but are not limited to: polyesters (e.g., polyethylene terephthalate (PET), polyester naphthalate, and polycarbonate), polyolefins (e.g., linear, branched, and cyclic polyolefins), polyvinyls (e.g., polyvinyl chloride, polyvinylidene chloride, polyvinyl acetals, polystyrene, polyacrylates, and the like), cellulose ester bases (e.g., cellulose triacetate, cellulose acetate), polysulphones such as polyethersulphone, polyimides, silicones and other conventional polymeric films. Additional examples of suitable substrates can be found in, e.g., U.S. Pat. No. 6,975,067.

Optionally, the surface of the substrate can be pre-treated to prepare the surface to better receive the subsequent deposition of the nanowires or the conductive material. Surface pre-treatments serve multiple functions. For example, they enable the deposition of a uniform nanowire dispersion layer. In addition, they can immobilize the nanowires on the substrate for subsequent processing steps. Moreover, the pre-treatment can be carried out in conjunction with a patterning step to create patterned deposition of the nanowires. As described in WO 2007/02226, pre-treatments can include solvent or chemical washing, heating, deposition of an optional patterned intermediate layer to present an appropriate chemical or ionic state to the nanowire dispersion, as well as further surface treatments such as plasma treatment, UV-ozone treatment, or corona discharge.

The transparent conductor coating 110 can be prepared in a variety of ways and can be prepared from a variety of transparent conductive materials. Examples of transparent conductive materials that are suitable include nanowires and conductive polymers. Nanowires are particularly suitable, especially conductive nanowires. Any reference to a nanowire or nanowires herein refers to a conductive nanowire or conductive nanowires. Transparent conductor coating and transparent conductive layer are used interchangeably, herein.

Conductive nanowires include metal nanowires and other conductive particles having high aspect ratios (e.g., higher than 10). Examples of non-metallic conductive nanowires include, but are not limited to, carbon nanotubes (CNTs), certain metal oxide nanowires (e.g., vanadium pentoxide), metalloid nanowires (e.g., silicon), conductive polymer fibers and the like. Nanowires can be described using other terms, such as for example filaments, fibers, rods, strings, strands, whiskers, or ribbons.

As used herein, “metal nanowire” refers to a metallic wire comprising elemental metal, metal alloys or metal compounds (including metal oxides exhibiting metallic conduction). At least one cross sectional dimension of the metal nanowire is less than 500 nanometers, less than 200 nanometers, or even less than 100 nanometers. As noted, the metal nanowire has an aspect ratio (length:width) of greater than 10, greater than 50, or even greater than 100. Suitable metal nanowires can be based on any metal, including without limitation, silver, gold, copper, nickel, and gold-plated silver.

The metal nanowires can be prepared by known methods in the art. In particular, silver nanowires can be synthesized through solution-phase reduction of a silver salt (e.g., silver nitrate) in the presence of a polyol (e.g., ethylene glycol) and polyvinyl pyrrolidone). Large-scale production of silver nanowires of uniform size can be prepared according to the methods described in, e.g., Xia, Y. et al., Chem. Mater. (2002), 14, 4736-4745, and Xia, Y. et al., Nanoletters (2003) 3(7), 955-960. More methods of making nanowires, such as using biological templates, are disclosed in WO 2007/022226.

In certain embodiments, the nanowires are dispersed in a liquid and a nanowire layer on the substrate is formed by coating the liquid containing the nanowires onto the substrate and then allowing the liquid to evaporate (dry) or cure. The nanowires are typically dispersed in a liquid to facilitate more uniform deposition onto the substrate by using a coater or sprayer.

Any non-corrosive liquid in which the nanowires can form a stable dispersion (also called “nanowire dispersion”) can be used. Generally, the nanowires are dispersed in water, an alcohol, a ketone, ethers, hydrocarbons or an aromatic solvent (benzene, toluene, xylene, etc.). Typically, the liquid is volatile, having a boiling point of no more than 200 degrees C., no more than 150 degrees C., or no more than 100 degrees C.

In addition, the nanowire dispersion may contain additives or binders to control viscosity, corrosion, adhesion, and nanowire dispersion. Examples of suitable additives or binders include, but are not limited to, carboxy methyl cellulose (CMC), 2-hydroxy ethyl cellulose (HEC), hydroxy propyl methyl cellulose (HPMC) methyl cellulose (MC), poly vinyl alcohol (PVA), tripropylene glycol (TPG), and xanthan gum (XG), and surfactants such as ethoxylates, alkoxylates, ethylene oxide and propylene oxide and their copolymers, sulfonates, sulfates, disulfonate salts, sulfosuccinates, phosphate esters, and fluorosurfactants (e.g., ZONYL by DuPont).

In one example, a nanowire dispersion, or “ink” includes, by weight, from 0.0025% to 0.1% surfactant {e.g., a preferred range is from 0.0025% to 0.05% for ZONYL FSO-100), from 0.02% to 4% viscosity modifier (e.g., a preferred range is 0.02% to 0.5% for HPMC), from 94.5% to 99.0% solvent and from 0.05% to 1.4% metal nanowires. Representative examples of suitable surfactants include ZONYL FSN, ZONYL FSO, ZONYL FSH, Triton (×100, ×114, ×45), Dynol (604, 607), n-Dodecyl b-D-maltoside and Novek. Examples of suitable viscosity modifiers include hydroxypropyl methyl cellulose (HPMC), methyl cellulose, xanthan gum, polyvinyl alcohol, carboxy methyl cellulose, hydroxy ethyl cellulose. Examples of suitable solvents that may be present in a nanowire dispersion that includes the aforementioned binders or additives, include water and isopropanol.

If it is desired to change the concentration of the dispersion from that disclosed above, the percent concentration of the solvent can be increased or decreased. In some desirable embodiments, the relative ratios of the other ingredients, however, can remain the same. In particular, the ratio of the surfactant to the viscosity modifier is generally in the range of about 80:1 to about 0.01:1; the ratio of the viscosity modifier to the nanowires is preferably in the range of about 5:1 to about 0.000625:1; and the ratio of the nanowires to the surfactant is generally in the range of about 560:1 to about 5:1. The ratios of components of the dispersion may be modified depending on the substrate and the method of application used. The typical viscosity range for the nanowire dispersion is between about 1 and 1000 cP.

The nanowire dispersion or conductive layer is applied to the substrate at a given thickness, in an effort to achieve desirable optical and electrical properties. This application is performed using known coating methods, such as slot coating, roll coating, Mayer rod coating, dip coating, curtain coating, slide coating, knife coating, gravure coating, notch bar coating or spraying, yielding a nanowire or conductive layer on the substrate. This coating step can be performed either as a roll-to-roll process or in a piece-part fashion. Following the deposition, the liquid of the dispersion is typically removed by evaporation. The evaporation can be accelerated by heating (e.g., using a dryer). The resulting conductive layer or nanowire layer may require post-treatment to render it more electrically conductive. This post-treatment can be a process step involving exposure to heat, plasma, corona discharge, UV-ozone, or pressure as further described in WO 2007/02226. Optionally coating the substrate with a conductive layer or nanowire layer can be followed by hardening or curing the conductive layer or nanowire layer.

Optionally, a conductive layer or nanowire layer can be coated onto a substrate by a process wherein the layer is delivered to the substrate surface using means other than liquid dispersion coating. For example, a nanowire layer can be dry-transferred to a substrate surface from a donor substrate. As a further example, nanowires can be delivered to a substrate surface from a gas phase suspension.

In one specific embodiment, a layer of aqueous dispersion of nanowires (Cambrios CLEAROHM Ink-N-G4-02, Part Number NKA722, Lot Number 12A0014TC) was applied to a PET substrate in the range 10 to 25 micrometers thick using a slot die coating technique. The coating formulation (e.g. % total solids by wt. and % silver nanowire solids by wt.) can be selected, along with the coating and drying process conditions, to create a nanowire layer with designed electrical and optical properties, e.g. a desired sheet resistance (Ohm/Sq) and optical properties such as transmission (%) and haze (%).

In other embodiments, the conductive layer can comprise a conductive polymer such as PEDOT instead of nanowires. A layer of aqueous dispersion of conductive polymer (e.g. Clevios F. E. PEDOT:PSS) was applied to a PET film in the range of 10-50 um thick with a Meyer rod. The coating formulation (e.g. % total solids by wt. and % conductive polymer solids by wt.) can be selected, along with the coating and drying process conditions, to create a conductive layer with designed electrical and optical properties, e.g. sheet resistance (Ohm/Sq) and optical properties transmission (%) and haze (%).

The nanowire layer that results from coating nanowires on a substrate (e.g., from a nanowire dispersion) includes nanowires and optionally binder or additives. The nanowire layer generally includes an interconnected network of nanowires. The nanowires that make up the nanowire layer are generally electrically connected to each other, leading approximately or effectively to a sheet conductor. The nanowire layer includes open space between the individual nanowires that make up the layer, leading to at least partial transparency (i.e., light transmission). Nanowire layers having an interconnected network of nanowires with open space between the individual nanowires may be described as transparent conductor layers.

Typically, the optical quality of the nanowire layer can be quantitatively described by measurable properties including light transmission and haze. “Light transmission” refers to the percentage of an incident light transmitted through a medium. In various embodiments, the light transmission of the conductive nanowire layer is at least 80% and can be as high as 99.9%. In various embodiments, the light transmission of the conductive layer such as the nanowire layer is at least 80% and can be as high as 99.9% (e.g., 90% to 99.9%, 95% to 99.5%, 97.5% to 99%). For a transparent conductor in which the conductive layer or nanowire layer is deposited or laminated (e.g., coated) on a substrate (e.g., a transparent substrate), the light transmission of the overall structure may be slightly diminished as compared with the light transmission of the constituent nanowire layer. Other layers that may be present in combination with the conductive layer or nanowire layer and the substrate, such as an adhesive layer, anti-reflective layer, anti-glare layer, may improve or diminish the overall light transmission of the transparent conductor. In various embodiments, the light transmission of the transparent conductor comprising a conductive layer such as a nanowire layer deposited or laminated on a substrate and one or more others layers can be at least 50%, at least 60%, at least 70%, at least 80%, at least 90%, or at least 91%, and may be as high as at least 91% to 99%.

Haze is an index of light diffusion. It refers to the percentage of the quantity of light separated from the incident light and scattered during transmission. Haze is often a production concern and is typically caused by surface roughness and embedded particles or compositional heterogeneities in the medium. In accordance with ASTM Standard No. D1003-11, haze can be defined as the proportion of transmitted light that is deflected by an angle greater than 2.5 degrees. In various embodiments, the haze of the conductive layer or nanowire layer is no more than 10%, no more than 8%, no more than 5%, no more than 2%, no more than 1%, no more than 0.5%, or no more than 0.1% (e.g., 0.1% to 5% or 0.5 to 2%). For a transparent conductor in which the conductive layer or nanowire layer is deposited or laminated (e.g., coated) on a substrate (e.g., a transparent substrate), the haze of the overall structure may be slightly increased as compared with the haze of the constituent nanowire layer. Other layers that may be present in combination with the conductive layer or nanowire layer and the substrate, such as an adhesive layer, anti-reflective layer, anti-glare layer, may improve or diminish the overall haze of the transparent conductor comprising a nanowire layer. In various embodiments, the haze of the transparent conductor comprising a conductive layer or a nanowire layer deposited or laminated on a substrate can be no more than 10%, no more than 8%, no more than 5%, no more than 2%, no more than 1%, no more than 0.5%, or no more than 0.1% (e.g., 0.1% to 5% or 0.5 to 2%). Clarity relates to the proportion of transmitted light that is deflected by an angle that is greater than 0 degrees and less than 2.5 degrees, with higher clarity being associated with less such deflected light.

The sheet resistance, transmission, and haze of a conductive layer or a nanowire layer can be tailored by varying certain attributes of the layer and its constituent materials such as the nanowires. Regarding the nanowires, they can be varied, for example, in composition (e.g., Ag, Cu, Cu—Ni alloy, Au, Pd), length (e.g., 1 micrometer, 10 micrometers, 100 micrometers, or greater than 100 micrometers), cross-sectional dimension (e.g., diameter of 10 nanometers, 20 nanometers, 30 nanometers, 40 nanometers, 50 nanometers, 75 nanometers, or greater than 75 nanometers). Regarding the conductive layer comprising the nanowires, it can be varied, for example, in its other components (e.g., cellulosic binders, processing aids such as surfactants, or conductance enhancers such as conducting polymers) or its area density of nanowires (e.g., greater than 10 per square millimeter, greater than 100 per square millimeter, greater than 1000 per square millimeter, or even greater than 10000 per square millimeter). Accordingly, the sheet resistance of the conductive layer or nanowire layer may be less than 1,000,000 Ohm/Sq, less than 1,000 Ohm/Sq, less than 100 Ohm/Sq, or even less than 10 Ohm/Sq (e.g., 1 Ohm/Sq to 1,000 Ohm/Sq, 10 Ohm/Sq to 500 Ohm/Sq, 20 Ohm/Sq to 200 Ohm/Sq, or 25 to 150 Ohm/Sq). The transmission of the conductive layer or nanowire layer may be at least 80% and can be as high as 99.9% (e.g., 90% to 99.9%, 95% to 99.5%, or 97.5% to 99%). The haze of the conductive layer or nanowire layer may be no more than 10%, no more than 8%, no more than 5%, no more than 2%, no more than 1%, no more than 0.5%, or no more than 0.1% (e.g., 0.1% to 5% or 0.5 to 2%).

To the article of FIG. 1A, resist matrix material 120 is selectively applied to the transparent conductor coating surface 110 in a pattern to form the article of FIG. 1B. FIG. 1B shows electrically insulating substrate 100 with transparent conductor coating 110 and selectively applied resist matrix material 120 in the form of a pattern. A wide range of resist matrix material patterns can be applied in this way. Examples of suitable pattern geometries include single or multiple discrete (i.e., separated) pattern elements or shapes. Examples of suitable pattern geometries that include multiple discrete pattern elements include patterns comprising a series of parallel, spaced apart, elongate pattern elements. Elongate pattern elements include, for example, rectangles, ellipses, traces of varying width (e.g., a series of corner-connected diamonds), branched traces, mesh traces enclosing open cells, and combinations thereof.

The resist matrix material is a material that can be applied to a conductive layer or a nanowire layer on a substrate (e.g., patterned, for example by printing, onto one or more regions of a conductive layer on a substrate), and upon being so applied render the conductive layer more adherent or protected from, for example protected from wet chemical etching, on the substrate (e.g., in one or more regions where the resist matrix material is patterned). Suitable printing processes include, for example, inkjet, gravure, flexographic, and screen printing. The resist matrix materials in many embodiments are transparent, especially in regions of articles where one or both of transparency and invisibility are required, but in some embodiments, the resist matrix material may be non-transparent. The resist matrix material may be non-transparent in embodiments where one or both of transparency and invisibility are not required, such as for example, when the resist matrix material is present in regions of an article such as a touch display sensor article where the region does not overlap a viewable region of the display.

In certain embodiments, the resist matrix material comprises a polymer and desirably an optically clear polymer. Examples of suitable polymeric resist matrix materials include, but are not limited to: polyacrylics such as polymethacrylates, polyacrylates and polyacrylonitriles, polyvinyl alcohols, polyesters (e.g., polyethylene terephthalate (PET), polyester naphthalate, and polycarbonates), polymers with a high degree of aromaticity such as phenolics or cresol-formaldehyde (NOVOLACS), polystyrenes, polyvinyltoluene, polyvinylxylene, polyimides, polyamides, polyamideimides, polyetherimides, polysulfides, polysulfones, polyphenylenes, and polyphenyl ethers, polyurethane (PU), epoxy, polyolefins (e.g. polypropylene, polymethylpentene, and cyclic olefins), acrylonitrile-butadiene-styrene copolymer (ABS), cellulosics, silicones and other silicon-containing polymers (e.g. polysilsesquioxanes and polysilanes), polyvinylchloride (PVC), polyacetates, polynorbomenes, synthetic rubbers (e.g. EPR, SBR, EPDM), and fluoropolymers (e.g., polyvinylidene fluoride, polytetrafluoroethylene (TFE) or polyhexafluoropropylene), copolymers of fluoro-olefin and hydrocarbon olefin (e.g., LUMIFLON), and amorphous fluorocarbon polymers or copolymers (e.g., CYTOP by Asahi Glass Co., or TEFLON AF by Du Pont).

In other embodiments, the resist matrix material comprises a prepolymer. A “prepolymer” refers to a mixture of monomers that can polymerize or a mixture of oligomers or partial polymers that can copolymerize and/or crosslink to form the polymeric matrix, or a combination of both, as described herein. It is within the knowledge of one skilled in the art to select, in view of a desirable polymeric matrix, a suitable monomer or partial polymer.

In some embodiments, the prepolymer is photo-curable, i.e., the prepolymer polymerizes and/or cross-links upon exposure to irradiation. Resist matrix materials based on photo-curable prepolymers can be patterned by exposure to irradiation in selective regions, or by selective placement of the prepolymer on the substrate followed by uniform exposure to irradiation. In other embodiments, the prepolymer is thermal-curable, which can be patterned in a similar manner, though exposure to a heat source is used in place of exposure to irradiation.

Typically, the resist matrix material is applied as a liquid. The resist matrix material may optionally comprise a solvent (e.g., during application). Optionally, the solvent may be removed during the application process, for example before over-coating with the strippable polymer layer. Any non-corrosive solvent that can effectively solvate or disperse the resist matrix material can be used. Examples of suitable solvents include water, an alcohol, a ketone, tetrahydrofuran, hydrocarbons (e.g. cyclohexane) or an aromatic solvent (benzene, toluene, xylene, etc.). The solvent can be volatile, having a boiling point of no more than 200° C., no more than 150° C., or no more than 100° C.

In some embodiments, the resist matrix material may comprise a cross-linker, a polymerization initiator, stabilizers (including, for example, antioxidants, and UV stabilizers for longer product lifetime and polymerization inhibitors for greater shelf-life), surfactants and the like. In some embodiments, the resist matrix material may further comprise a corrosion inhibitor.

In some embodiments, the resist matrix material has a thickness between about 10 nanometers and 50 micrometers, between about 20 nanometers to 1 micrometer, between about 50 nanometers and 50 micrometers, or between about 50 nanometers to 200 nanometers. In some embodiments, the resist matrix material has a refractive index of between about 1.30 and 2.50, between about 1.40 and 1.70, or between about 1.35 and 1.80.

It will be understood that this step encompasses not only the application of the protective resist matrix material, but also any drying and/or curing steps used to generate the final protective resist matrix material. It will also be understood that the protective resist matrix material protects the transparent conductor material on which it is disposed from the wet chemical etching processing steps and also remains covering the transparent conductor material after the wet chemical etching process. As such the protective resist matrix material is chosen so as to not be removed during the wet chemical etching process.

To the article of FIG. 1B is selectively applied a conductive contact material 130 (for example, a conductive paste composition that is converted through drying or curing to a solid conductive contact material) in a pattern to portions of the transparent conductor layer to generate the article shown in FIG. 1C. In FIG. 1C the conductive contact material 130 is shown to overlap with the resist matrix material 120, but this is optional and conductive contact material 130 may be flush with the edge of resist matrix material 120.

The precursor article thus produced has the transparent conductor layer surface divided into subregions. The subregions comprise first subregions comprising the transparent conductor coating exposed, second subregions comprising the transparent conductor coating and the protective resist matrix material, and third subregions comprising the conductive coating in contact with the conductive contact material pattern. As shown in FIG. 1C, the conductive contact material pattern 130 may partially overlap the protective resist matrix material 120, however, in some embodiments the conductive contact material pattern 130 may not overlap the protective resist matrix material 120, but may be flush to the edge of the protective resist matrix material 120 (not shown). As with the protective resist matrix material, application of the conductive contact material pattern encompasses not only the application but also any drying and/or curing steps used to prepare the conductive contact from the conductive contact material pattern. Typically the conductive contact material comprises a paste material comprising conductive metal such as silver and is applied as a slurry, paste or ink and is dried to form the conductive contact 130. In some embodiments, the conductive contact material is deposited from the vapor phase, for example by sputter coating or evaporation coating. Such conductive contact materials may have a thickness in the range of, for example, 0.1 to 10 micrometers, in some embodiments 0.2 to 5 micrometers, in other embodiments 0.3 to 3 micrometers. Useful processes for patterning a sputter coated or evaporation coated conductive contact material include shadow mask deposition.

After the precursor article described above and shown in FIG. 1C is prepared, the surface is chemically etched using a wet chemical etching agent to generate the article shown in FIG. 1D.

A wide variety of wet chemical etching agents are useful in the practice of this disclosure.

A particular challenge that arises in the use of patterned transparent conductors based on nanowires is simultaneously achieving electrical contact to a transparent conductive nanowire pattern element and protecting the nanowire pattern element from environmental factors that may degrade electrical properties (e.g., atmospheric corrosive species). These requirements may be met in part by introduction of additional materials: a transparent resist matrix that overlays and protects the nanowires in the region of the transparent conductive pattern element and an electrically conductive contact material in electrical contact with the transparent conductive pattern element. The practical implementation of these multiple materials necessarily includes their patterning in registration, such that the conductive contact and the resist matrix are each positioned in predetermined locations relative to the nanowire transparent conductor, which is itself patterned. The patterning of these multiple materials in registration may be achieved by various multi-step processes. Some processes may be preferred over other processes, for example on the basis of technical effect or on the basis of simplicity or cost. One criterion for process preference is the number of steps in the process, with more preferred processes having fewer process steps. Another criterion for process preference is the avoidance of particularly challenging steps. The present disclosure report multi-step processes for the patterning in registration of a transparent resist matrix, an electrically conductive contact material, and a nanowire transparent conductor, with the advantage of a small number of process steps and with the advantage of avoiding the need to remove some or all of a resist matrix.

As mentioned above, wet chemical etching agents can not only remove, or usefully reduce or eliminate the electrical conductance of, the exposed transparent conductor material, but also can remove at least in part the conductive contact material. However, as has been discovered and is disclosed herein, if the transparent conductor layer is sufficiently thin relative to the conductive contact, conditions have been identified that are suitable for removing, or usefully reducing or eliminating the electrical conductance of, the transparent conductive layer material without removing the entire conductive contact, preserving the function of the conductive contact. Some non-zero amount of the conductive contact can be lost due to etching, however the practices disclosed herein minimize this loss.

A variety of factors can be used to control the etching process so as to remove all or essentially all of the exposed transparent conductor material and removing a minimum of the conductive contact. Among these factors are time to which the precursor article is exposed to the etching agent, concentration of the etching agent, chemical composition of the etching agent, temperature at which the etching is carried out, and whether physical agitation is used to assist the etching agent in removing the exposed transparent conductor material.

In FIG. 1D, substrate 100 has modified transparent conductor layer 110′, where the exposed portions of transparent conductor layer 110 have been removed (the removed portions of the transparent conductor layer are not visible in the cross sectional view). Protective resist matrix material is essentially unchanged by the etching process, but the removal of the exposed transparent conductor material renders the protective resist material patterned layers and the transparent conductor material 110′ under the patterned protective resist layer 120 into discrete conductive traces. Conductive contact 130′ typically is slightly altered from conductive contact 130 for example if a small amount of conductive material has been removed during the etching process, but the conductive contact remains intact and is fully functional in that it remains in electrical contact with the remains of the transparent conductor layer 110′, and in that it can be contacted electrically at its exposed surface. FIG. 1D further shows that regions of transparent conductor layer not covered by either the resist matrix pattern 120 or conductive contact 130′ have been removed.

Thus, in the etching process, the transparent conductor material in the first subregions comprising the exposed transparent conductive layer are selectively removed. The transparent conductor material in the second subregions comprising the transparent conductive layer and the resist matrix, and the transparent conductor material in the third subregions comprising the transparent conductive layer in contact with a conductive contact are not removed or are not completely removed. Additionally, some of the conductive contact material of the conductive contact may be removed, but as mentioned above the modified conductive contact remains functional.

The resulting article of FIG. 1D is shown in the alternate top view of FIG. 1E. In FIG. 1E, regions of the electrically insulating substrate 100 have been exposed, the conductive traces (protective resist matrix patterned layers with transparent conductor material beneath the pattern) are shown but only the protective resist matrix 120 is visible in this view. The discrete electrically conductive traces are shown to be in contact with the conductive contact 130′. The dotted lines shown in the surface of the protective resist matrix 120 illustrate the end of the protected conductive trace and the solid line delineates the region where the conductive contact 130′ overlaps the protective resist matrix 120.

It should be noted that while FIG. 1E shows that all of the exposed transparent conductor layer has been removed, there may be a small amount of residual transparent conductor material present in these locations. However, the amount of residual transparent conductor material, if present, is sufficiently small that the conductive traces (covered by protective resist matrix 120) are discrete, meaning that an electrical current is not transmitted between adjacent traces, and therefore the spaces between adjacent traces are essentially insulating.

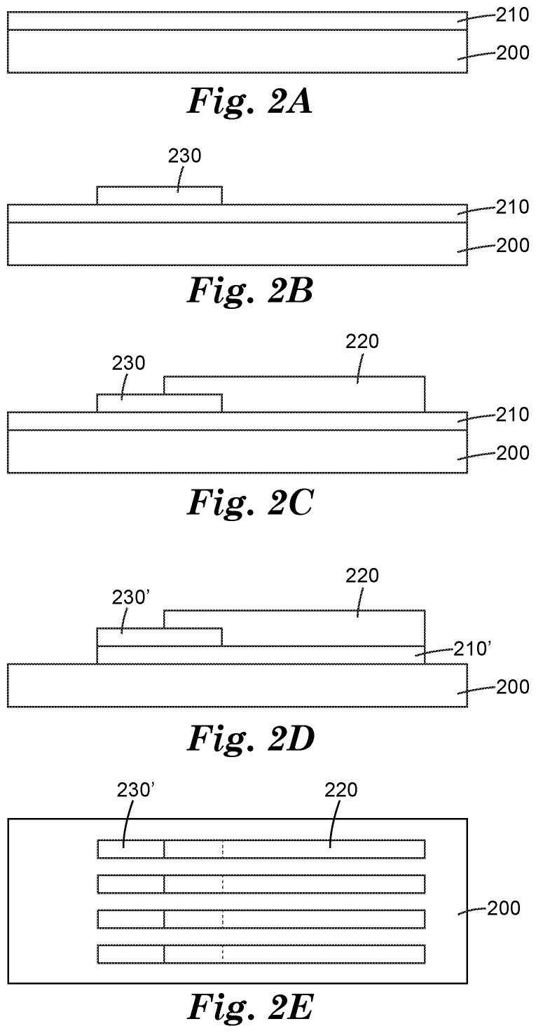

In the second embodiment of the method of preparing conductive articles, like in the first embodiment described above, a precursor article is first prepared and then processed in an etching step. The material descriptions provided above for the first embodiment are the same materials used in the second embodiment. Therefore, these material descriptions will not be repeated. A first step in the preparation of the precursor article is providing an electrically insulating substrate with a substantially continuous transparent conductor coating over at least a portion of the substrate surface. This article is shown in FIG. 2A, which shows substrate 200 with transparent conductor coating 210. The electrically insulating substrate and transparent conductor coating are as described above for the first embodiment.

To the article of FIG. 2A is selectively applied a conductive contact material 230 (for example, a conductive paste composition that is converted through drying or curing to a solid conductive contact material) in a pattern to portions of the transparent conductor layer to generate the article shown in FIG. 2B. The conductive contact material (e.g. paste compositions) and methods of curing and/or drying the conductive material compositions to form the conductive contacts 230 have been discussed in detail above.

Protective resist matrix material is selectively applied in a pattern to the transparent conductive layer of the article of FIG. 2B, and the protective resist material may also be applied to a portion of the surface of the conductive contact 230 to form the article of FIG. 2C. FIG. 2C shows electrically insulating substrate 200 with transparent conductor coating 210, conductive contact 230, and selectively applied resist matrix material 220 in the form of a pattern. A wide range of patterns can be applied in this way. The protective resist matrix materials and the patterns formed with the protective resist materials have been described in detail above.

The precursor article thus produced has the transparent conductor coating layer surface divided into subregions. The subregions comprise first subregions comprising the transparent conductor coating exposed, second subregions comprising the transparent conductor coating and the protective resist matrix material, and third subregions comprising the conductive coating in contact with the conductive paste pattern. As shown in FIG. 2C, the protective resist matrix material 220 may partially overlap the conductive contact 230, however, the protective resist matrix material 220 does not fully overlap the exposed surface of conductive contact 230, and if desired, the protective resist matrix material 220 can be made to not overlap the conductive contact 230, but the protective resist matrix material 220 may be flush to the edge of the conductive contact 230 (not shown).

After the precursor article described above and shown in FIG. 2C is prepared, the surface is chemically etched using a wet chemical etching agent to generate the article shown in FIG. 2D. The etching agents and procedures are described in detail above.

In FIG. 2D, substrate 200 has modified transparent conductor layer 210′, where the exposed portions of transparent conductor layer 210 have been removed (the removed portions of the transparent conductor layer are not visible in the cross sectional view). Protective resist matrix material is essentially unchanged by the etching process, but the removal of the exposed transparent conductor material renders the protective resist material patterned layers and the transparent conductor material 210′ under the patterned protective resist layer 220 into discrete conductive traces. Conductive contact 230′ may be slightly altered from conductive contact 230 as a small amount of conductive material may be removed during the etching process, but the conductive contact remains intact and is fully functional in that it remains in electrical contact with the remains of the transparent conductor layer 210′.

Thus, in the etching process, the transparent conductor material in the first subregions comprising the exposed transparent conductive layer are selectively removed. The transparent conductor material in the second subregions comprising the transparent conductive layer and the resist matrix, and the transparent conductor material in the third subregions comprising the transparent conductive layer in contact with a conductive contact are not removed or are not completely removed.

The resulting article of FIG. 2D is shown in the alternate top view of FIG. 2E. In FIG. 2E, regions of the electrically insulating substrate 200 have been exposed, the conductive traces (protective resist matrix patterned layers with transparent conductor material beneath the pattern) are shown but only the protective resist matrix 220 is visible in this view. The discrete electrically conductive traces are shown to be in contact with the conductive contact 230′. The dotted lines in the protective resist matrix 220 illustrate the end of the conductive contact 230′ that is covered by the protective matrix, and the solid line delineates the edge of the protective matrix 220.

It should be noted that while FIG. 2E shows that all of the exposed transparent conductor layer has been removed, there may be a small amount of residual transparent conductor material present in these locations. However, the amount of residual transparent conductor material, if present, is sufficiently small that the conductive traces (covered by protective resist matrix 220) are discrete, meaning that an electrical current is not transmitted between adjacent traces, and therefore the spaces between adjacent traces are essentially insulating.

Also disclosed herein are conductive articles prepared by the above described methods. Since two different method embodiments were described, two different embodiment types of articles are described. The first articles described are the articles prepared by the first method described above.

The first embodiment conductive article comprises an electrically insulating substrate, with a conductive region on the substrate, a non-conductive region on the substrate, and an exposed conductive contact. The conductive region comprises a conductive pattern comprising a transparent conductor and a resist matrix. The exposed conductive contact comprises a first major surface and a second major surface. The first major surface of the conductive contact is in contact with the transparent conductor, and also contacts a portion of the resist matrix. In many embodiments, where the conductive contact contacts the resist matrix, the conductive contact overlaps the resist matrix. In some embodiments, the conductive contact may be flush with the resist matrix so that the only contact between the conductive contact and the resist matrix is edge contact, however, typically at least some of the conductive contact overlaps a portion of the resist matrix. Having the conductive contact overlap the resist matrix helps to provide a continuous protective barrier for the transparent conductor, whereas having the conductive contact being only in edge contact with the resist matrix could provide an opening between them through which chemical etchant could seep and contact the transparent conductor.

Each of the elements of the articles has been described above. In many embodiments, at least a portion or portions of the electrically conductive article is a transparent article. Transparent articles typically have a luminous transmission of at least 80% over at least a portion of the visible light spectrum (about 400 to about 700 nm).

A wide range of electrically insulating substrates are suitable, as described above. In some embodiments, the electrically insulating substrate comprises a glass substrate, a polymeric substrate, or a release liner.

In many embodiments, the transparent conductor comprises a plurality of interconnecting nanowires. Nanowires and interconnecting nanowires are described in detail above. In some embodiments, the conductive pattern comprises a series of elongate pattern elements and the nonconductive regions comprise at least the regions between the series of elongate pattern elements. Typical resist matrix materials are described above. In some embodiments the resist matrix comprises an acrylate polymer. In most embodiments, the resist matrix is a non-tacky matrix.

The first embodiment conductive articles may be prepared from precursor articles, where the precursor article comprises an electrically insulating substrate with a substantially continuous transparent conductor coating over at least a portion of the substrate surface, where the substantially continuous transparent conductor coating surface is divided into subregions, the subregions comprising first subregions comprising the conductive coating exposed, second subregions comprising the transparent conductor coating and a protective resist matrix, and third subregions comprising the transparent conductor coating in contact with a conductive contact. The conductive contact may optionally overlap with portions of the protective resist matrix, or the conductive contact may be flush to the edge of the protective resist matrix. The second subregions comprising the transparent conductor coating and a protective resist matrix comprise a conductive pattern. The first subregions comprising the transparent conductor coating are capable of being selectively removed by chemical etching. The second subregions comprising the transparent conductor coating and a protective resist matrix, and the third subregions comprising the transparent conductor coating in contact with a conductive contact are not removed or are not completely removed by the chemical etching.

The second conductive article embodiment comprises an electrically insulating substrate, a conductive region on the substrate, the conductive region comprising a conductive pattern comprising a transparent conductor and a protective resist matrix, a non-conductive region on the substrate, and an exposed conductive contact comprising a first major surface, a second major surface. The entire first major surface of the conductive contact is in contact with the transparent conductor. At least a portion of the second major surface of the conductive contact is exposed, and the conductive contact is in contact with the resist matrix, and a portion of the second major surface of the conductive contact may optionally be covered by a portion of the resist matrix. As was described above for the first conductive article embodiment, the contact with the conductive contact and the resist matrix may be flush, but having the resist matrix overlap the conductive contact helps to provide a continuous protective barrier for the transparent conductor, whereas having the conductive contact being only in edge contact with the resist matrix could provide an opening between them through which chemical etchant could seep and contact the transparent conductor.

Each of the elements of the articles has been described above. In many embodiments, the electrically conductive article is a transparent article. Transparent articles typically have a luminous transmission of at least 80% over at least a portion of the visible light spectrum (about 400 to about 700 nm).

A wide range of electrically insulating substrates are suitable, as described above. In some embodiments, the electrically insulating substrate comprises a glass substrate, a polymeric substrate, or a release liner.

In many embodiments, the transparent conductor comprises a plurality of interconnecting nanowires. Nanowires and interconnecting nanowires are described in detail above. In some embodiments, the conductive pattern comprises a series of elongate pattern elements and the nonconductive regions comprise at least the regions between the series of elongate pattern elements. Typical resist matrix materials are described above. In some embodiments the resist matrix comprises an acrylate polymer. In most embodiments, the resist matrix is a non-tacky matrix.

The second embodiment conductive articles may be prepared from precursor articles, as described above. The precursor article comprises an electrically insulating substrate with a substantially continuous transparent conductor coating over at least a portion of the substrate surface, where the substantially continuous transparent conductor coating surface is divided into subregions, the subregions comprising first subregions comprising the conductive coating exposed, second subregions comprising the transparent conductor coating and a protective resist matrix, and third subregions comprising the transparent conductor coating in contact with a conductive contact which may be a pattern of a conductive paste. The protective resist matrix may optionally overlap with portions of the conductive contact. The second subregions comprising the transparent conductor coating and a resist matrix comprise a conductive pattern. The first subregions comprising the transparent conductor coating are capable of being selectively removed by chemical etching. The second subregions comprising the transparent conductor coating and a resist matrix, and the third subregions comprising the transparent conductor coating in contact with a conductive contact are not removed or are not completely removed by the chemical etching.

### EXAMPLES

These examples are merely for illustrative purposes only and are not meant to be limiting on the scope of the appended claims.

Table of Abbreviations

| Material | |
|---|---|
| Abbreviation | Description |
| Nanowire | CLEAR-OHM INK-N G4-02 commercially available from |
| Formulation | Cambrios Technologies Corporation, Sunnyvale, CA. |
| Etchant-1 | Commercially available etchant, “Bleach-fix” from |
| | Eastman Kodak, Rochester, NY. |
| DI water | De-ionized water |
| PET Film | A 5 mil (127 micrometers) thick film of polyethylene |
| | terephthalate, commercially available as MELINEX ST- |
| | 504 from DuPont, Wilmington, DE. |
| Overcoat | UV cured FLEXOCURE SIGMA clear varnish ink |
| Material | #UFR00061 FC Force Transparent White commercially |
| | available from Fling Group Print Media North America, |
| | Batavia, IL. |
| Silver Paste | SILVER PRINT II commercially available from GC |
| | Electronics, Rockford, IL. |

### Test Methods

### Etch Method

In the present examples, etching of the Nanowire coated film was carried out using the commercial etching material, Etchant-1. The Bleach-fix chemistry is a commercially available etchant developed by the photographic industry for the purpose of etching silver. This etchant is shipped in two separate containers and is labeled “part A” and “part B,” to be mixed in a ratio of 1:1. This solution was further diluted with water prior to etching. For the experiments described herein, the dilution factor for A to B to DI water was 1:1:48.

Two etchant delivery methods were used; still bath etching and spray box etching. For still bath etching, the Etchant-1 was diluted as described above in a beaker and stirred for 15 minutes using a VWR-371 stir plate set to level 8 prior to experimentation. Substrates were dipped into the etch bath for an indicated length of time before removing and rinsing in 2 in-line DI water rinse baths. Afterwards, the etched substrates were placed on a Text-wipe (Berkshire SUPER POLX 1200, 100% knitted polyester, 9″ by 9″ (23 centimeters×23 centimeters)) and both sides were dried using an air or nitrogen gun. Samples were stored in plastic bags with Text-wipes between the samples. A spray box, consisting of a spray nozzle approximately six inches (15 centimeter) in front of a vertical plate that held substrate samples, was used for spray etching. The etchant solution was contained in the bottom of the box during etch experiments, where it does not contact the sample. A pump (with varying pressure) was used to spray liquid onto the substrate. Before using the spray etch box, 2 liters of DI water was added and the pump was turned on for a few minutes, in order to rinse the box and remove any residues from the device. This rinse solution was then drained and 2 liters of the etch solution (prepared as described) was added to the spray etch box. The pump was turned on for 1 minute at a pressure of 1.5 bar (150 kiloPascals) prior to placing substrates in the etch box. The pump was turned off each time a substrate was added or removed from the box. To etch a substrate, the plate was removed, dried with a paper towel, and tape was used to attach the substrate to the middle of the plate. The plate was then placed back into the spray etch box, and the pump was turned on for an indicated length of time. The pump was then turned off, the plate removed from the etch box, and the substrate removed from the plate. Next, the samples were rinsed in 2 in-line DI water rinse baths before drying on a Text-wipe using an air or nitrogen gun. Samples were stored in plastic bags with Text-wipes between the samples. After the etching experiment was completed, 2 liters of DI water was again added to the spray etch box and the pump was turned on for 1 minute to rinse before draining the liquid from the spray box device.

### Electrical Measurements

Samples were patterned with a protective overcoat into alternating bars with overcoat (conduction post-etch) and no overcoat (non-conduction post-etch) to resemble a component of a touch screen sensor. After removing nanowires by etching from the non-overcoated region to render the region non-conductive, the resistance across each bar was measured by first applying silver paste to the end of each conductive bar, allowing the silver paste to dry in air, and subsequently physically connecting each end of a bar with a multi-meter test leads, and recording the resistance. Electrical isolation of the bars was measured by connecting one multi-meter test lead to one side of a bar, and the other multi-meter test lead to the opposite side of an adjacent bar. If a measurable resistance can be measured from at least one bar to an adjacent bar, then the sample is labeled as not electrically isolated.

### Comparative Example C1: Demonstration of Electrical Isolation of Discrete Patterns

A conductive material-coated substrate was prepared by coating a layer of Nanowire Formulation on PET film, where the coating thickness was predetermined to yield a nominal sheet resistance of 40Ω/□ (40 Ohms per square). After coating the Nanowire Formulation, Overcoat Material was deposited onto the Nanowire Formulation-coated film by flexographic printing as a resist matrix material, using a pattered photopolymer stamp. The printed pattern yielded 19 coated bars, with uncoated regions between the coated bars.

The Nanowire Formulation-coated films, patterned with a protective overcoat, were etched for various amounts of time using a spray etch bath. Details of the etch times and the electrical data for the first 10 bars out of 19 patterned bars total for this sample set can be found in Table 1 (bars labeled 1-10). Electrical data recorded was the resistance in kiloOhms (kΩ). If no value is recorded in Table 1, this indicated that there was no measurable resistance in the kΩ range. For etch times from 1 to 40 seconds, the majority of the bars represented in Table 1 were conductive, however there was no electrical isolation between bars. No measurable resistance was generally observed in samples that were etched for 45 to 120 seconds, as well as no measurable resistance could be noted in adjacent bars (indicating electrical isolation if the bars were measured conductive). The protective matrix prevents the ability to form an electrical connection with silver paste applied after the etching.

TABLE 1

| Etch | | | | | | | | | | | Electrical |
|---|---|---|---|---|---|---|---|---|---|---|---|
| Time (s) | 1 | 2 | 3 | 4 | 5 | 6 | 7 | 8 | 9 | 10 | Isolation? |
| 1 | — | 1.03 | 42.1 | 0.56 | 1.2 | 2.4 | 300.1 | 3.6 | 1.12 | 6.42 | N |
| 2 | 0.28 | 0.74 | 125.3 | 0.1 | 1.42 | 1.32 | 2.01 | 0.33 | 0.25 | 2.65 | N |
| 5 | 10.2 | 0.04 | 28.5 | 36.2 | 1.36 | 2.22 | 1.52 | 86.7 | 0.31 | 0.33 | N |
| 10 | — | 0.89 | 0.15 | 0.89 | 0.42 | 1.56 | 2.12 | 5.39 | 61.2 | 1.02 | N |
| 15 | 0.63 | 0.96 | 1.2 | 8.14 | 6.32 | 4.45 | 0.01 | 1.54 | 3.84 | 0.85 | N |
| 20 | 0.33 | 52.3 | — | — | 14.3 | 342.1 | 7.92 | 1.21 | 2.02 | 2.04 | N |
| 25 | 0.31 | 62.1 | 2.42 | 5.46 | 0.38 | 23.4 | 0.45 | 7.43 | — | — | N |
| 30 | 2.45 | 0.12 | 6.27 | 4.56 | 4.53 | 1 | 6.91 | 244.3 | 0.003 | 10.1 | N |
| 35 | 3.18 | 0.78 | 0.65 | 0.29 | 101.6 | 9.63 | 3.2 | 1.58 | 0.92 | 94.1 | N |
| 40 | 0.45 | 0.96 | 1.26 | 3.42 | 0.61 | 2.51 | 0.33 | — | — | — | N |
| 45 | — | — | — | — | — | — | — | — | — | — | Y |
| 50 | — | — | — | — | — | — | — | — | — | — | Y |
| 60 | — | — | — | — | — | 6.45 | — | — | — | — | Y |
| 70 | — | — | — | — | — | — | — | — | — | — | Y |
| 80 | — | — | — | — | — | — | — | — | — | — | Y |
| 90 | — | — | — | — | — | — | — | — | — | — | Y |
| 100 | — | — | 17.82 | — | — | 42.1 | — | — | — | — | Y |
| 110 | — | — | 0.005 | — | — | 1.52 | — | — | — | — | Y |
| 120 | — | — | — | — | — | — | — | — | — | — | Y |

### Example 1

A conductive material-coated substrate was prepared by coating a layer of Nanowire Formulation on PET Film, where the coating thickness was predetermined to yield a nominal sheet resistance of 40Ω/□ (40 Ohms per square). After coating the Nanowire Formulation, Overcoat Material was deposited onto the Nanowire Formulation-coated film by flexographic printing as a resist matrix material, using a pattered photopolymer stamp. The printed pattern yielded 19 coated bars, with uncoated regions between the coated bars.

Silver Paste was carefully painted onto the edge of each bar, being careful not to span the width of 2 bars, and allowed to air dry. After painting on the silver, samples were etched using a still bath for various times between 20 and 65 seconds. Electrical measurements for resistance across the first 10 bars are shown in Table 2, along with the electrical isolation data. The two samples with the shortest etch times (20 and 25 seconds) were the only samples without electrical isolation. Also, these samples had a much lower resistance than what was measured on bars of samples etched for at least 30 seconds, indicating incomplete removal of the nanowire material in the uncoated regions. It appears that etching for longer than necessary to produce electrically isolated bars (30 seconds in this case) does not negatively affect the resistance or the electrical isolation of the bars. Visually, the silver paste appeared unaffected by the silver etchants. The concentration of silver etchants used in this study are relatively dilute, and although some of the silver from the silver paste may be removed by the etching process, it was not enough to impact electrical connection on the samples prepared in these experiments.

TABLE 2

| Etch Time | | | | | | | | | | | Electrical |
|---|---|---|---|---|---|---|---|---|---|---|---|
| (s) | 1 | 2 | 3 | 4 | 5 | 6 | 7 | 8 | 9 | 10 | Isolation |
| 20 | 0.491 | 0.405 | 0.34 | 0.309 | 0.295 | 0.286 | 0.282 | 0.276 | 0.275 | 0.281 | No |
| 25 | 1.916 | 1.494 | 1.39 | 1.043 | 0.897 | 0.853 | 0.787 | 0.792 | 0.75 | 0.778 | No |
| 30 | 11.03 | 8.99 | 9.1 | 9.21 | 9.8 | 9.75 | — | 9.63 | 9.26 | 9.44 | Yes |
| 35 | 9.95 | 8.51 | 9.2 | 9.71 | 9.85 | 10.23 | 9.82 | 11.93 | 8.98 | 9.05 | Yes |
| 40 | 11.66 | 10.44 | 10.8 | 10.89 | 10.19 | 10.44 | 10.74 | 10.76 | 10.05 | 6.84 | Yes |
| 45 | 9.84 | 9.3 | 9.56 | 9.43 | 9.54 | 9.69 | 9.44 | 10.3 | 9.3 | 9.07 | Yes |
| 50 | 12.32 | 9.88 | 10 | 9.76 | 10.07 | 10.88 | 10.42 | 10.71 | — | 9.83 | Yes |
| 55 | 12.06 | 10.05 | 9.8 | 9.71 | 9.62 | 10.08 | 9.91 | 10.4 | 10.65 | 11.45 | Yes |
| 60 | 9.79 | 7.81 | 8.88 | 8.51 | 8.46 | 8.36 | 8.75 | — | 9.36 | — | Yes |
| 65 | 11.4 | 9.57 | 9.67 | 9.2 | 9.06 | 9.47 | 9.63 | — | 10.01 | 10.99 | Yes |

What is claimed is:

1. A conductive article comprising:
an electrically insulating substrate;
a conductive region on the substrate, the conductive region comprising a conductive pattern comprising a transparent conductor and a resist matrix;
a non-conductive region on the substrate; and
an exposed conductive contact comprising a first major surface and a second major surface, wherein a portion of the first major surface of the conductive contact is in contact with the transparent conductor, and a portion of the first major surface of the conductive contact is in contact with a portion of the resist matrix, and wherein the second major surface of the conductive contact is exposed.

2. The article of claim 1, wherein the transparent conductor comprises a plurality of interconnecting nanowires.

3. The article of claim 1, wherein the resist matrix comprises a non-tacky polymeric matrix.

4. The article of claim 1, wherein the electrically insulating substrate comprises a glass substrate, a polymeric substrate, or a release liner.

5. The article of claim 1, wherein the electrically conductive article is a transparent article.

6. The article of claim 1, wherein the conductive pattern comprises a series of elongate elements, and the nonconductive regions comprise at least the regions between the series of elongate elements.

7. The article of claim 1, wherein the conductive article is prepared from a precursor article, the precursor article comprising:
an electrically insulating substrate comprising a substantially continuous transparent conductor coating over at least a portion of the substrate surface, wherein the substantially continuous transparent conductor coating surface is divided into subregions, the subregions comprising:
first subregions comprising the transparent conductor coating exposed;
second subregions comprising the transparent conductor coating and a pattern of protective resist matrix material; and
third subregions comprising the transparent conductor coating in contact with a conductive contact, wherein the conductive contact comprises a first major surface and a second major surface, wherein a portion of the first major surface is in contact with the transparent conductor coating, and a portion of the first major surface is in contact with the protective resist matrix material, and the second major surface is exposed; and
wherein the exposed transparent conductor coating of the first subregions is capable of being selectively removed by chemical etching, whereas the transparent conductor coating in the second subregions comprising the transparent conductor coating and the resist matrix, and the transparent conductor coating in the third subregions comprising the transparent conductor coating in contact with the conductive contact are not removed or are not completely removed.

8. A method of preparing a conductive article comprising:
preparing a precursor article, wherein preparing the precursor article comprises:
providing an electrically insulating substrate comprising a substantially continuous transparent conductor coating over at least a portion of the substrate surface;
selectively applying a resist matrix material to portions of the substantially continuous transparent conductor coating to yield a pattern of resist matrix material with an exposed surface; and
selectively applying a conductive contact composition in a pattern to portions of the transparent conductor coating surface, and to at least portions of the exposed surface of the resist matrix material, such that the transparent conductor coating surface is divided into subregions, the subregions comprising:
first subregions comprising the transparent conductor coating exposed;
second subregions comprising the transparent conductor coating and the pattern of resist matrix material; and
third subregions comprising the transparent conductor coating in contact with the conductive contact composition pattern, wherein the conductive contact composition pattern is also in contact with a portion of the exposed surface of the resist matrix material;
optionally curing or drying the resist matrix material and optionally drying or curing the conductive contact composition; and
chemically etching the precursor article such that the transparent conductor coating in the first subregions comprising the exposed transparent conductor coating is selectively removed, and wherein the transparent conductor coating in the second subregions comprising the transparent conductor coating and the resist matrix and the transparent conductor coating in the third subregions comprising the transparent conductor coating in contact with the conductive contact are not removed or are not completely removed.

9. The method of claim 8, wherein after chemical etching the first subregions are essentially nonconductive.

10. The method of claim 8, wherein selectively applying a resist matrix material to portions of the substantially continuous transparent conductor coating in a pattern comprises applying the resist matrix material in a series of elongate elements.

11. The method of claim 8, wherein the conductive contact composition comprises a conductive metallic paste that upon drying forms the conductive contact.

12. A conductive article comprising:
an electrically insulating substrate;
a conductive region on the substrate, the conductive region comprising a conductive pattern comprising a transparent conductor and a resist matrix;
a non-conductive region on the substrate; and
an exposed conductive contact comprising a first major surface and a second major surface, wherein the entire first major surface of the conductive contact is in contact with the transparent conductor, and wherein at least a portion of the second major surface of the conductive contact is exposed and the conductive contact is in contact with the resist matrix and optionally a portion of the second major surface of the conductive contact is overlapped by the resist matrix.

13. The article of claim 12, wherein the transparent conductor comprises a plurality of interconnecting nanowires.

14. The article of claim 12, wherein the resist matrix comprises a non-tacky polymeric matrix.

15. The article of claim 12, wherein the electrically insulating substrate comprises a glass substrate, a polymeric substrate, or a release liner.

16. The article of claim 12, wherein the electrically conductive article is a transparent article.

17. The article of claim 12, wherein the conductive pattern comprises a series of elongate elements, and the nonconductive regions comprise at least the regions between the series of elongate elements.

18. The article of claim 12, wherein the conductive article is prepared from a precursor article, the precursor article comprising:
an electrically insulating substrate comprising a substantially continuous transparent conductor coating over at least a portion of the substrate surface, wherein the substantially continuous transparent conductor coating surface is divided into subregions, the subregions comprising:
first subregions comprising the transparent conductor coating exposed;
second subregions comprising the transparent conductor coating and a pattern of protective resist matrix material; and
third subregions comprising the transparent conductor coating in contact with a conductive contact, wherein the conductive contact comprises a first major surface and a second major surface, wherein the entire first major surface is in contact with the transparent conductor coating, and at least a portion of the second major surface is exposed, and a portion of the second major surface may optionally be in contact with the protective resist matrix material; and
wherein the exposed transparent conductor coating in the first subregions comprising the transparent conductor coating is capable of being selectively removed by chemical etching, whereas the transparent conductor coating in the second subregions comprising the transparent conductor coating and the resist matrix, and the transparent conductor coating in the third subregions comprising the transparent conductor coating in contact with the conductive contact are not removed or are not completely removed.

19. A method of preparing a conductive article comprising:
preparing a precursor article, wherein preparing the precursor article comprises:
providing an electrically insulating substrate comprising a substantially continuous transparent conductor coating over at least a portion of the substrate surface;
selectively applying a conductive contact composition in a pattern to portions of the transparent conductor coating to form a conductive contact with an exposed surface; and
selectively applying a resist matrix material to portions of the substantially continuous transparent conductor coating and optionally to a portion of the exposed surface of the conductive contact composition in a pattern, such that the transparent conductor coating surface is divided into subregions, the subregions comprising:
first subregions comprising the transparent conductor coating exposed;
second subregions comprising the transparent conductor coating and the pattern of resist matrix material; and
third subregions comprising the transparent conductive coating in contact with the conductive contact composition pattern wherein a portion of the conductive contact composition pattern is in contact with the resist matrix material;
optionally curing or drying the resist matrix material and optionally drying or curing the conductive contact composition; and
chemically etching the precursor article such that the transparent conductor coating in the first subregions comprising the exposed transparent conductor coating is selectively removed, and wherein the transparent conductor coating in the second subregions comprising the transparent conductor coating and the resist matrix, and the transparent conductor coating in the third subregions comprising the transparent conductor coating in contact with a conductive contact are not removed or are not completely removed.

20. The method of claim 19, wherein after chemical etching the first subregions are essentially nonconductive.

21. The method of claim 19, wherein selectively applying a resist matrix material to portions of the substantially continuous conductive coating in a pattern comprises applying the resist matrix material in a series of elongate elements.

22. The method of claim 19, wherein the conductive contact composition comprises a conductive metallic paste that upon drying forms the conductive contact.
